(19) United States
(12) Patent Application Publication
(10) Pub. No.: US 2008/0201092 A1
(43) Pub. Date: Aug. 21, 2008

(54) Waveform Display Method And Apparatus

(76) Inventor: Matthew Sean Connolly, Queensland (AU)

Correspondence Address: NEIFELD IP LAW, PC, 4813-B EISENHOWER AVENUE, ALEXANDRIA, VA, 22304, US

(21) Appl. No.: 11/915,360

(22) PCT Filed: Aug. 22, 2006
(86) PCT No.: PCT/AU2006/001213

§ 371 Date: Nov. 23, 2007

(30) Foreign Application Priority Data
Aug. 22, 2005 (AU) 2005904542

(51) Int. Cl. G01R 13/02

(52) U.S. Cl. 702/67

(57) ABSTRACT

A method and apparatus for displaying an audio signal as an improved waveform includes a processor for determining samples of the audio signal which represent a waveform based on positions of pixels in the waveform and a time scale of the waveform, calculating minimum and maximum amplitudes of the samples for each pixel on a time axis and calculating intensities of frequency components of the samples which cannot be represented at the time scale of the waveform. The apparatus includes a display coupled to be in communication with the processor for displaying the samples as an improved waveform of amplitude versus time wherein the intensities of the frequency components are represented in the new waveform by shades of a single colour.

### FIELD OF THE INVENTION

The present invention relates to an improved waveform display. In particular, but not exclusively, the present invention relates to a method and apparatus for displaying an audio signal as an improved waveform.

### BACKGROUND TO THE INVENTION

Many audio recording, editing and production systems, or Digital Audio Workstations (DAWs), use a waveform to represent audio recordings on a computer screen or video monitor. The most common method of displaying a waveform is the use of a two-dimensional graph representing amplitude against time. The problem with amplitude versus time waveforms is that the vast majority of audio recordings contain more information than can be represented on a computer screen or video monitor at one time. Therefore, DAWs have implemented a system of zooming in and zooming out on both the amplitude and time scales to better represent the sound and overcome the lack of detail represented on the computer screen or video monitor. However, repeatedly zooming in and out to view the detail is particularly laborious and inefficient.

A waveform is a two-dimensional graph representing amplitude against time. Typically, time is represented on the horizontal axis and amplitude on the vertical axis. The reverse arrangement of the axes is feasible, but not commonly used, if at all. Typically, waveforms are monochrome, in that the waveform is represented with a single colour. Different colours are often used within DAW systems to represent different recordings in a single project. For example, a vocal track may be coloured green, whilst a drum track may be coloured blue and so on.

In this field, the terms “microscopic” and “macroscopic” are used in relation to displays of audio signals. Any waveform showing individual samples making up the signal on the screen is considered microscopic. Any waveform where pixels on the screen represent a period of time comprising more than one sample is considered macroscopic.

With reference to FIG. 1, which shows 0.008 seconds of an audio signal, where a waveform is displayed at a microscopic time scale, the individual frequency components can be represented as a simple curve, as would be represented by a mathematical function.

With reference to FIG. 2, which shows 2.0 seconds of an audio signal, where a waveform is displayed at a macroscopic time scale, the individual frequency components cannot be seen. Instead, an envelope of the maximum and minimum amplitudes of the audio signal is displayed. In a macroscopic view, there is no means of representing the frequency components lying within the envelope of maximum and minimum amplitude. The range of frequencies which cannot be represented includes all frequencies above a lower limit, which is a function of the scale of the time axis. That is, where a display has a small time scale representing a small duration of time, there are only a small number of higher frequencies which cannot be displayed. Where a display has a large time scale representing a large duration of time, there is a larger range of medium and high frequencies which cannot be displayed.

The parameters of sound that are useful to a user of a DAW system are the peak amplitude of a sound signal, the root-mean-square (RMS) amplitude of the sound signal and the frequency content, i.e. the amplitude or energy of the signal in certain frequency bands.

The peak amplitude is easily represented by the maximum and minimum frequency component values and is well executed in the majority of modern DAW systems.

The RMS amplitude has a simple yet strong mathematical background, but is often quite difficult to calculate and represent with complex audio recordings.

One method of displaying frequency content is via a spectrogram. With reference to FIG. 3, a spectrogram is a graph of frequency on the vertical axis against time on the horizontal axis in which multiple spectra computed from a sound signal are displayed together. The spectra are typically computed using Fourier transforms and are displayed parallel to each other and parallel to the vertical axis. The strength of a given frequency component at a given time in the sound signal is represented by a shade or colour and multiple colours and/or shades are used in each spectra of the multiple spectra represented in a single spectrogram. However, this method requires a significant amount of computation and is better suited to specialised analysis applications. Furthermore, spectrograms can be quite difficult to read and are not very well suited to audio recording, editing and production applications.

Another type of apparatus and method for displaying audio data as a discrete waveform is disclosed in U.S. Pat. No. 5,634,020 assigned to Avid Technology, Inc. A smoothing operation is applied to a selected portion of audio data to obtain an average value for the sample and the average value is compared against a user-set or calculated threshold to generate a discrete waveform representative of the audio sample. The apparatus and method also includes an option of determining a root-mean-square of each sample of audio data during the comparison process. However, the root-mean-square is not directly represented in the display. The discrete waveform is displayed as either a series of coloured bars of equal height or as bars of the same colour, but of different heights, the colours/heights selected according to a value of the corresponding sample of audio.

This apparatus and method provides an alternative display method that aids in locating features of the audio data, such as breaks in sound and dialogue. However, frequency component detail is not represented in this display. Also, the improvement therein resides in displaying the results of a comparison between the signal or derived analysis of a signal with a threshold which is user defined or derived from another signal, and therefore, does not necessarily apply to the entire waveform, or apply directly to the waveform in its own right. Furthermore, the Avid method and apparatus does not address the aforementioned problem of zooming in and out repeatedly.

Another type of waveform display method and apparatus is disclosed in U.S. Pat. No. 6,184,898 assigned to Comparisonics Corporation. A signal is partitioned into a plurality of consecutive time segments, which are then processed to extract frequency-dependent information that characterises each segment. The frequency-dependent information may depend on a dominant frequency or a subordinate frequency determined by the greatest or smallest amplitude respectively. The frequency spectrum is divided into bands and values are associated with each band. A value P is assigned to each time segment based on the band in which the characteristic frequency-dependent information falls. An amplitude variance V is also determined for each segment, the values P & V combining to create a signature that characterises each segment. The signatures are stored in memory and read to generate a display in which a column of pixels representing the time segment of the signal are represented in a particular colour. The colour depends at least on the frequency-dependent value P.

The Comparisonics method uses a Fast Fourier Transform or a Linear Prediction Algorithm to provide some frequency analysis of the time segment. A Fourier Transform is not a favourable method of analysis because it requires the time segments to have an even number of samples (2, 4, 6, 8, 10, etc.). A Fast Fourier Transform is even less flexible because it requires segments that are a power of 2 (2, 4, 8, 16, 32, 64, etc.). Thus, the relationship between the duration of the segment and the time period represented by any point on the display can be proven to be a point of weakness. Furthermore, the aforementioned problem of zooming in and out to view detail of the signal is again not addressed.

Another method is disclosed in U.S. Pat. No. 5,532,936 in the name of John W. Perry. In this invention, the audio signal is broken into a number of frequency bands, with a plurality of damped oscillators that are used to detect the presence of energy in certain frequency bands. This technique is more efficient and flexible than the Fourier Transform or Fast Fourier Transform methods. However, the technique is used to create a spectrogram and therefore suffers the same shortcomings as the abovementioned spectrogram display methods. In the spectrograms in this invention, the strength of the signal components are represented by pixels of varying intensity and/or colour. Low strengths are represented as blue pixels of low intensity and high strengths are represented as pink pixels of high intensity with intermediate strengths represented by pixels coded along the colour and intensity continuums in between.

In addition to the shortcomings in the display, the disclosed technique of using a damped oscillator to determine frequency content is also less flexible because each damped oscillator is designed to respond to a certain frequency band. As the user zooms in and out on a waveform display, thus changing the time scale axis, the frequencies that can be shown on the display also change. Therefore, as the time scale changes, a change in the design of the damped oscillators would also be required in order to provide useful functionality at a range of time scales. Redesigning the damped oscillators would also require the audio signal to be re-processed with the new damped oscillator designs, which would be inefficient.

Both the Comparisonics and Avid methods and apparatus and the method of Perry employ multiple colours that can cause confusion in cases where different colours are used to represent different recordings in a project, such as vocals in one colour, drums in another colour and so on.

Hence, there is a need for a system, method and/or apparatus that addresses or ameliorates at least the aforementioned prior art problem of needing to zoom in and out on a signal to have an indication of the detail contained within the signal.

In this specification, the terms “comprises”, “comprising” or similar terms are intended to mean a non-exclusive inclusion, such that a method, system or apparatus that comprises a list of elements does not include those elements solely, but may well include other elements not listed.

### SUMMARY OF THE INVENTION

In one form, although it need not be the only or indeed the broadest form, the invention resides in a method of displaying an audio signal as an improved waveform including the steps of:

a) determining samples of the audio signal which represent a waveform based on positions of the pixels in the waveform and a time scale of the waveform;

b) calculating minimum and maximum amplitudes of the samples for each pixel on the time axis;

c) calculating intensities of frequency components of the samples which cannot be represented at the time scale of the waveform for each pixel on the time axis; and

d) displaying the samples as an improved waveform of amplitude versus time wherein the intensities of the frequency components are represented in the improved waveform by shades of a single colour.

Suitably, darker shades represent a higher intensity of high frequency components that cannot be displayed at the time scale of the waveform and lighter shades represent a lower intensity of high frequency components that cannot be displayed at the time scale of the waveform or vice versa.

Suitably, a gradient between a darkest shade and a lightest shade of the single colour used in the improved waveform is linear or curved. The method may include:

e) calculating root-mean-square amplitudes of the samples for each pixel on the time axis.

The method may further include representing the root-mean-square amplitudes of the samples in a profile of amplitude versus colour shade.

Suitably, the shade of a pixel comprising said improved waveform is indicative of the root-mean-square amplitude of the samples in the time interval represented by said pixel.

The method may further include representing the root-mean-square amplitudes of the samples in the improved waveform as a region of pixels of a darker shade within pixels of a lighter shade, said lighter shade pixels representing maximum and minimum amplitudes of the samples.

The method may further include repeating steps a)-d) when the time scale of the improved waveform is changed.

Suitably, steps b) and c) and optionally e) are performed in a single step.

Suitably, the colour of the waveform is the same as the colour employed for a recording type, such as vocals, bass or the like.

The method may include creating a plurality of overview packets as a summary of a recording of the audio signal enabling some or all of steps a) to d) to be performed without directly accessing the recording.

Suitably, the summary of the audio recording comprises approximations of one or more of the following: minimum amplitudes, maximum amplitudes, a root-mean-square amplitude, high frequency component energies.

The method may include transmitting a summary of processing conducted in a main processor to a graphical processor to enable the graphical processor to construct an image of the improved waveform.

In another form, the invention resides in an apparatus for displaying an audio signal as an improved waveform, said apparatus comprising:

a processor for:
determining samples of the audio signal which represent a waveform based on positions of the pixels in the waveform and a time scale of the waveform;
calculating maximum and minimum amplitudes of the samples for each pixel on a time axis; and
calculating intensities of frequency components of the samples which cannot be represented at the time scale of the waveform for each pixel on a time axis; and

a display coupled to be in communication with the processor for displaying the samples as an improved waveform of amplitude versus time wherein the intensities of the frequency components are represented in the waveform by shades of a single colour.

Suitably, the processor comprises a main processor coupled to be in communication with a graphical processor, said graphical processor coupled to be in communication with the display.

Suitably, the main processor creates a plurality of overview packets as a summary of a recording of the audio signal enabling some or all of the steps performed in the main processor to be performed without directly accessing the recording.

Preferably, the main processor transmits the summary to the graphical processor to enable the graphical processor to construct an image of the improved waveform.

Further features of the present invention will become apparent from the following detailed description.

### BRIEF DESCRIPTION OF THE DRAWINGS

By way of example only, preferred embodiments of the invention will be described more fully hereinafter with reference to the accompanying drawings, wherein:

FIG. 1 shows an example of a prior art waveform on a microscopic scale;

FIG. 2 shows an example of a prior art waveform on a macroscopic scale;

FIG. 3 shows an example of a prior art spectrogram representing a single word;

FIG. 4 is a schematic representation of an apparatus according to an embodiment of the invention;

FIG. 5 is a flowchart representing a method according to an embodiment of the invention;

FIG. 6 shows an example of an improved waveform according to an embodiment of the invention;

FIG. 7 shows an example of a prior art waveform for the same signal represented in FIG. 6;

FIG. 8 shows an example of a prior art waveform resulting from zooming in on region B-B of the a prior art waveform of FIG. 7;

FIG. 9 shows an example of an improved waveform resulting from zooming in on region B-B of the improved waveform of FIG. 6;

FIG. 10 shows an example of an improved waveform resulting from zooming in on region C-C of the improved waveform of FIG. 9;

FIG. 11 shows an example of a prior art waveform resulting from zooming in on region C-C of the a prior art waveform of FIG. 8;

FIG. 12 shows an example of a graph of pixel shade versus amplitude illustrating an example of the shade of pixels representing the root-mean-square amplitude and the intensity of high frequency components; and

FIG. 13 is a schematic representation of an apparatus according to an alternative embodiment of the invention.

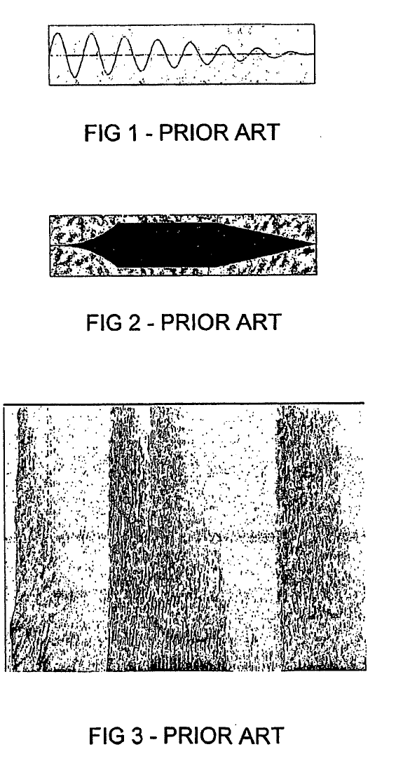

### DETAILED DESCRIPTION OF THE INVENTION

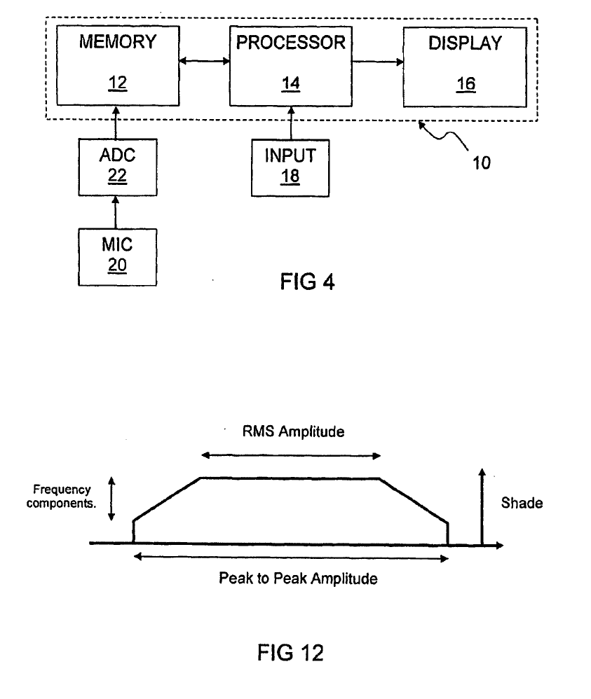

Referring to FIG. 4, there is provided an apparatus 10 for producing an improved waveform to display an audio signal. The apparatus 10 comprises a memory 12 for storing a signal, such as an audio signal, in digital format, which is coupled to be in communication with a processor 14 for processing samples of the signal. Processor 14 is coupled to be in communication with a display 16, such as a screen, for displaying the improved waveform. Input device 18, such as a mouse, is coupled to be in communication with the processor 14 to allow a user to make selections, for example, of samples of the signal and perform any other editing tasks.

The signal is stored in memory 12 as a file, such as an industry standard AIFF or WAVE file, or PCM (Pulse Code Modulated) data, and may be a recording from an original source via a microphone 20 coupled to an analogue-to-digital converter (ADC) 22. Alternatively, the file stored in memory 12 may be a recording from another source, such as a compact disc (CD), record, tape, electronic instrument (including guitars), synthesizer, tone generator or computer system which generates audio recordings.

The method of generating and displaying the improved waveform will now be described with reference to FIGS. 5-12.

With reference to FIG. 5, in step 100, an audio signal stored in memory 12 is extracted from the memory 12. In step 110, the method determines the samples of the audio signal that represent a waveform of the audio signal based on a position of the pixels in the waveform and a time scale of the waveform. Each pixel therefore represents a time period that is determined by its position and the scale of the time axis of the waveform. The method includes analyzing frequency components of the signal to determine the intensity of frequency components making up the signal during the time period associated with each pixel. The analysis concerns frequencies above a lower limit frequency which is a function of the time scale and corresponds to the time period of the represented pixel. The lower limit frequency is a frequency with a time period equal to the duration of two (2) pixels in the waveform. For a frequency component to be visible in a waveform, the waveform must clearly display a rise and fall of the signal. Therefore, only frequencies with a period greater than or equal to two (2) or more samples pixels in the waveform can be represented.

With reference to step 120, the minimum and maximum amplitudes of the samples for each pixel are calculated and in step 125, the root-mean-square amplitudes for each pixel are calculated. In step 130, the intensities of the frequency components that cannot be represented at the time scale of the waveform are calculated for each pixel. Whilst steps 120, 125 and 130 are shown in FIG. 5 as three separate steps, in one embodiment, steps 120, 125 and 130 are executed in a single step. Since step 125 is optional, where step 125 is omitted, steps 120 and 130 can be executed as separate steps or as a single step. In one embodiment, calculation of the intensities of the frequency components of a signal f(t) is performed according to equation (1):

$$\frac{{\int }_{{t}_{1}}^{{t}_{2}} \vert \frac{d f ( t )}{d t} \vert}{{t}_{2} - {t}_{1}} \qquad Eqn . ( 1 )$$

where t₁ and t₂ are the start time and end time respectively of the time period for the corresponding pixel.

In another embodiment, the intensities of the frequency components of a sample f(t) are calculated according to equation (2):

$$\sqrt{\frac{{\int }_{{t}_{1}}^{{t}_{2}} {( \frac{d f ( t )}{d t} )}^{2}}{{t}_{2} - {t}_{1}}} \qquad Eqn . ( 2 )$$

The inventor envisages that in a further embodiment, a Fourier Transform (FT) or a Fast Fourier Transform (FFT) could be employed to analyse the frequency components, although this is not preferred due to the aforementioned drawbacks of such algorithms. Once a FT or FFT is performed, a sum of the magnitude of frequency components would be carried out to determine the intensity of frequency components above the lower limit determined by the time scale.

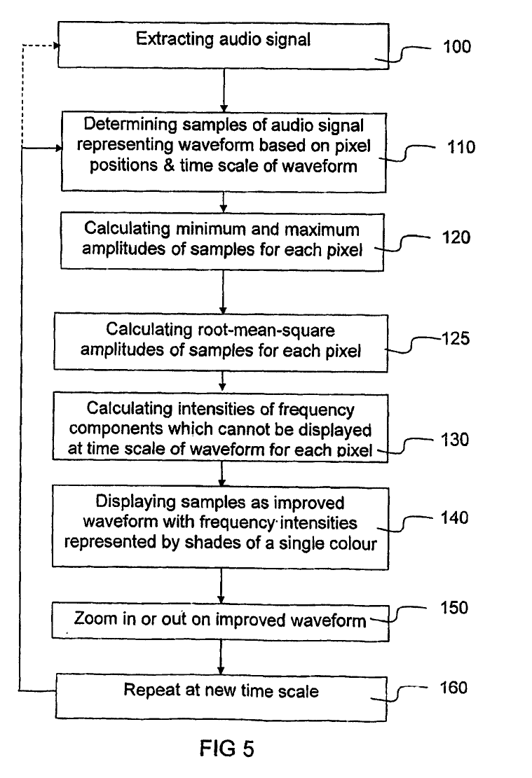

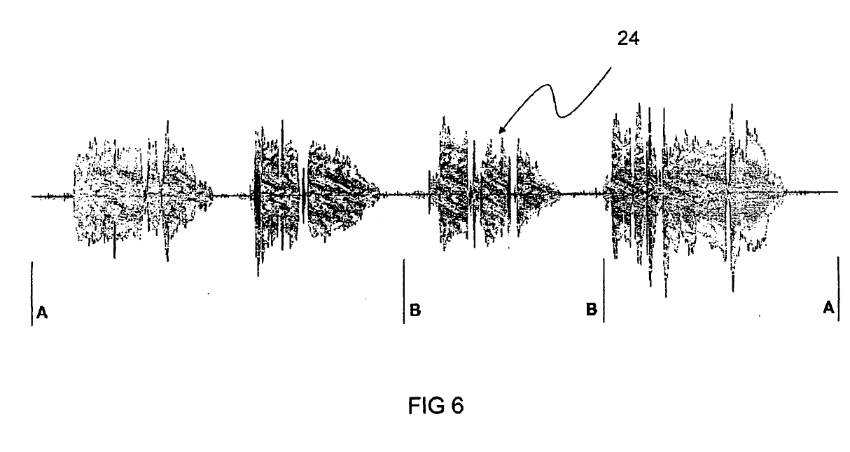

Referring to step 140 in the flowchart in FIG. 5 and to the improved waveform in FIG. 6, the method includes displaying the signal samples as an improved waveform 24 of time versus amplitude. In a preferred embodiment, time is represented on the horizontal axis and amplitude on the vertical axis, but in an alternative embodiment, the axes could be reversed, i.e., amplitude represented on the horizontal axis and time on the vertical axis. The improved waveform 24 is formed from a series of adjacent columns of pixels where each column of pixels corresponds to a duration of time of one or more samples of the signal, which depends on the position of the one or more samples on time axis and the scale of the time axis. The upper pixel of each column of pixels represents the maximum amplitude within the samples and the lower pixel of each column of pixels represents the minimum amplitude within the samples.

As shown in FIG. 6, the results of calculating the maximum and minimum amplitudes and the intensities of the frequency components of the one or more samples are represented in the improved waveform 24 by different shades of a single colour. A normal or default colour shade is specified for the pixels representing the improved waveform 24. The default colour shade may be specified by the application or by the user. The particular colour employed for the improved waveform 24 may be selected by the user to coincide with the particular recording type, e.g. the vocals, or the bass, or other instrument in the project.

There are many systems available for defining colours, each using a number of components. Among the most common systems are RGB (Red, Green and Blue), CMYK (Cyan, Magenta, Yellow and Key) and HSB (Hue, Saturation and Brightness). RGB is typically used in video and computer displays, because the components relate directly to the red, green and blue phosphors in a Cathode Ray Tube display, for example. CMYK is mostly used in print media industries, because the components relate directly to the cyan, magenta, yellow and key (usually black) inks used for printing on paper. The HSB colour system uses a different set of components, namely hue, saturation and brightness, which describe colours in terms more natural to an artist. Hue is a component that describes a range of colours from red through green through to blue, similar to the spectrum of colours in a rainbow. Saturation describes the intensity of a colour, which ranges from gray to vivid tones, for example describing the difference between tan and brown. Brightness describes the shade of a colour, from dark to light, ranging from black to a full intensity of the colour according to the values of the hue and saturation components.

Often, the description of colour in text relates to hue. Named colours, such as red, orange and blue correspond to colours in the rainbow and can be defined with values of the hue component in the HSB colour system.

In the existing display methods mentioned above, a variation in colour typically happens in the hue component. For example, different intensities in a spectrogram, or different dominant frequencies, are represented by a change in the hue of a colour thus creating a spectrum similar to the range of colours on the rainbow.

The present invention uses shades of a single colour, which maintain a constant hue. That is, the pixels comprising the improved waveform image have a constant value of the hue component and the brightness is varied to create a range of shades in a single colour.

In FIG. 6, some detail of the signal is visible for the particular time scale employed for the improved waveform 24. For example, the variations in maximum and minimum amplitude are clearly displayed. However, at this time scale, some frequency components of the signal cannot be displayed in detail. Nonetheless, in accordance with the present invention, the presence of the frequency components within the signal is displayed at this time scale by the single colour shading of pixels forming the improved waveform 24. In one embodiment, darker shades represent a higher intensity of frequency components that cannot be displayed at the current time scale of the waveform and lighter shades represent a lower intensity of frequency components that cannot be displayed at the current time scale of the waveform. In an alternative embodiment, lighter shades represent a higher intensity of frequency components and darker shades represent a lower intensity of frequency components.

In one embodiment, the gradient between the darkest shade and the lightest, default shade, which, in one embodiment, represent the maximum and minimum intensities of the frequency components respectively, is linear. Alternatively, the gradient between the shades may be curved to provide the best visual consistency across the range of time scales that can be viewed by zooming in and out on the improved waveform.

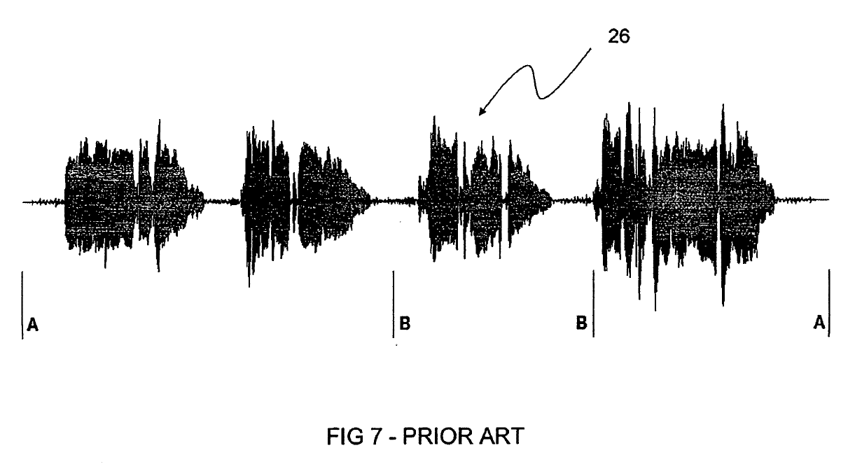

The improved waveform 24 generated by the present invention can be contrasted with a waveform for the same signal on the same time scale generated by a typical DAW. The typical prior art waveform 26 is shown in FIG. 7. Prior art waveform 26 displays similar information to the improved waveform 24 regarding the maximum and minimum amplitude, but the conventional, monochrome waveform 26 reveals no information about the frequency components or their location. To reveal further information, the user must zoom in on the relevant part of the prior art waveform 26. On this time scale the user is shown less overall information, requiring the user to constantly zoom in and zoom out to see the required detail and navigate within a project. In contrast, the waveform of the present invention shown in FIG. 6 reveals detail of the frequency components without zooming in on the waveform by virtue of the single colour shading of the pixels making up the waveform.

It will be appreciated that where reference is made herein to the invention and representing the frequency components in shades of colour, such as red, blue, green and the like, in some embodiments, a grey scale may be employed and therefore the expression “shades of colour” also includes shades of grey.

With reference to step 150 in FIG. 5, where the frequency components of the signal are highlighted by the shading, but cannot be displayed in detail at a particular time scale of the improved waveform, the desired region can be zoomed in upon as with a standard DAW. When a region is selected, the method of the present invention is repeated at the new time scale of the selected region, as represented by step 160. For example, the improved waveform 24 of FIG. 6 may represent 2 seconds of an audio signal. Frequency components on the millisecond scale cannot be displayed in detail in this waveform because of the limited resolution, which is determined by the number of pixels representing the improved waveform 24. However, the locations of the frequency components are highlighted by the single colour shading, the particular shading indicating the intensity of frequency components at each location. Selecting a desired point or region of the waveform, e.g. by clicking a pointer on that point or by clicking and selecting a region, such as with a mouse or the like, causes that region of the waveform to be zoomed in upon. The method is repeated and an improved waveform at a smaller time scale is displayed, i.e. the selected region is effectively magnified. FIG. 5 shows that the method is repeated from step 110 because usually the segment of audio being zoomed in upon has already been extracted from memory 12. However, in an alternative embodiment, where, for example, zooming out takes place, this may necessitate further data being extracted from the memory 12, in which case the method is repeated from step 100.

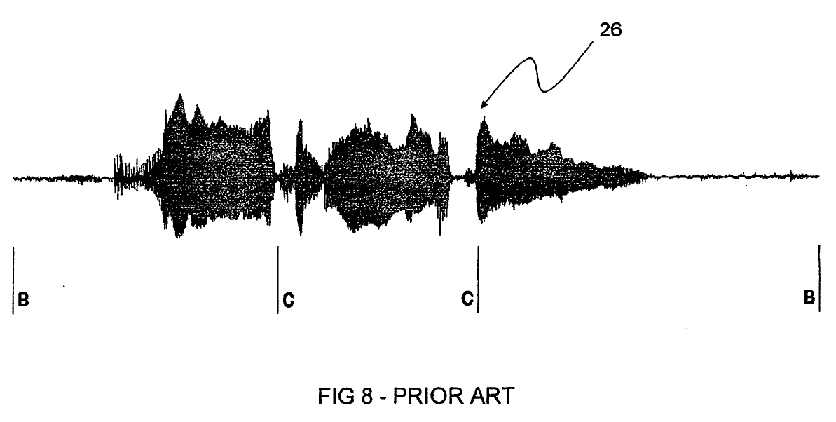

FIG. 8 shows the result of zooming in on part of the prior art waveform 26 shown in FIG. 7 between points B-B. At this smaller time scale, or greater magnification, more detail of the audio signal is revealed, but a shorter duration of the overall recording is shown. Again, the monochrome prior art waveform only shows the detail visible at the current time scale of the prior art waveform.

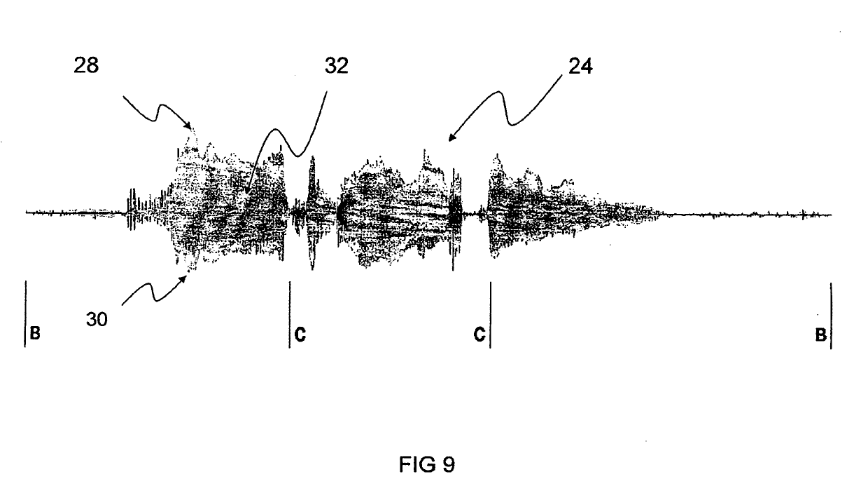

FIG. 9 shows the same duration and part of the audio signal (i.e. between points B-B) as shown in FIG. 8, but using an embodiment of the improved waveform display method of the present invention. In contrast, in this improved waveform, it can be seen that the improved waveform again reveals more information about the location and intensity of high frequency components than the prior art method for the same signal. This is true at any macroscopic time scale. The improved waveform in FIG. 9 shows some of the detail that was not evident in the improved waveform of FIG. 6. The improved waveform in FIG. 9 also shows darker and lighter shaded regions indicating further locations of frequency components that cannot be shown on the present time scale. Such detail is not present in the zoomed in prior art waveform shown in FIG. 8.

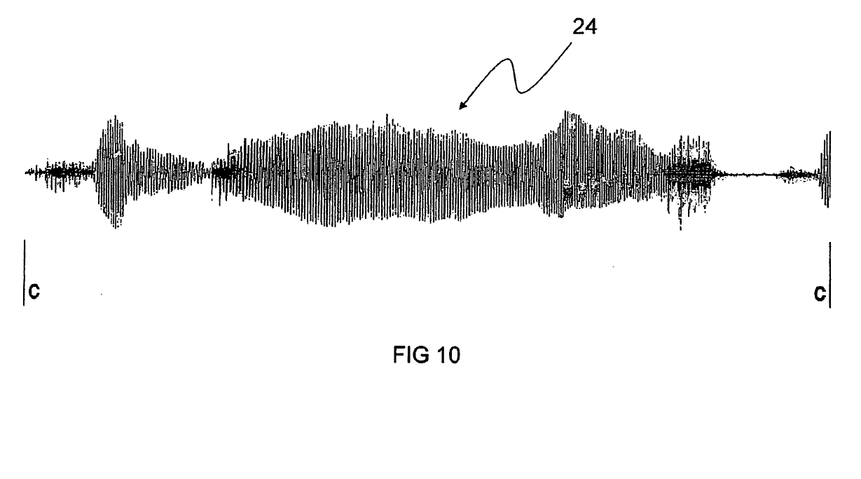

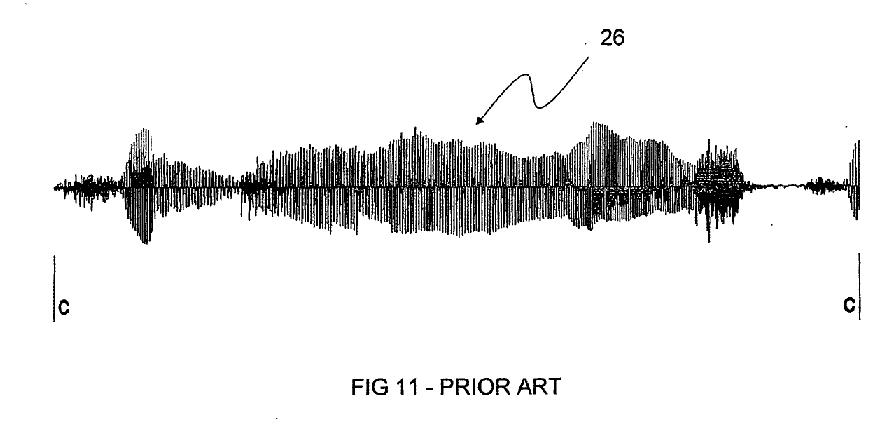

FIG. 10 shows the result of zooming in further on the improved waveform shown in FIG. 9 between the points C-C of the waveform. The improved waveform can be contrasted with the prior art waveform for the same region of the prior art waveform at the same magnification shown in FIG. 11. The single colour shading present in the improved waveform in FIG. 10 again provides further information about the signal that cannot be displayed at this time scale. Such information is not available in the monochrome prior art waveform at the same time scale as shown in FIG. 11.

In addition to showing the location of the frequency components in the improved waveform 24, in one embodiment, the improved waveform 24 also shows the RMS value of the signal. The shade of a pixel comprising the improved waveform 24 is indicative of a root-mean-square amplitude of the signal in the time interval represented by said pixel. Therefore, with reference to FIG. 12, the method may further include representing the root-mean-square (RMS) amplitude of the signal as a profile of amplitude versus shade. As shown, for example, in FIG. 9, the maximum amplitudes 28 and the minimum amplitudes 30 are represented in a lighter shade whereas the central region 32 is represented in a darker shade to represent the RMS amplitude. The RMS amplitude is always less than the peak-to-peak amplitude and therefore the RMS amplitude can be represented within the waveform as a shaded centre region. In practice this allows the RMS amplitude and the high frequency components to be represented simultaneously in the waveform in an intuitive manner which is consistent with microscopic time scales.

The analysis of a signal may be saved in memory or cached on disk, either as a separate file or as meta-data embedded into an audio file, to speed up the drawing process and to reduce memory requirements and access times.

To further improve efficiency, in one embodiment, the method of the present invention may include reducing the audio recording into a plurality of packets. Each packet corresponds to a time period within the audio recording and comprises a summary of the audio recording during that period. The duration of these packets is independent of the display and can be specified by the user or by the application. The summary may comprise approximations of values in an effort to reduce memory requirements and/or increase the speed of drawing the improved waveform 24 by removing the need to access the audio recording directly. The summary may contain approximations of values representing the minimum and maximum amplitude, the RMS amplitude and/or the high frequency energy of the period of the audio recording. Suitably, in order to maintain maximum quality of improved waveform images, summary packets are used only when the time period of the packet is less than the time period associated with each pixel along the time axis.

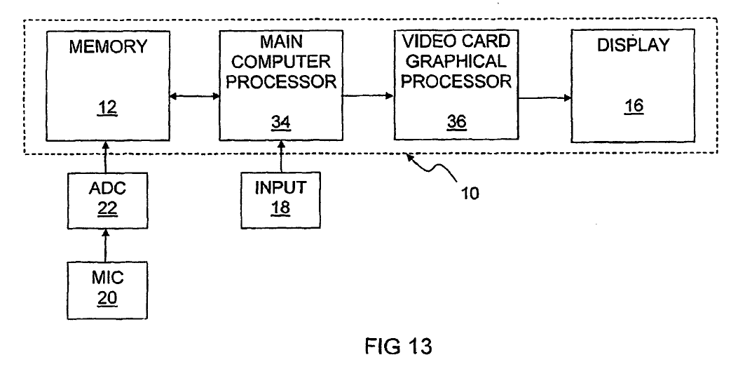

With reference to FIG. 13, in an alternative embodiment, the apparatus 10, comprises the same components as the first embodiment shown in FIG. 4, except that processor 14 is replaced by a main processor 34 coupled to be in communication with a graphical processor 36. In this embodiment, the workload of the processor 14 of the first embodiment is distributed between the main processor 34 and the graphical processor 36. Main processor 34 typically resides in a main part of a computer system with access to many computer peripherals, including the ADC 22 and the input devices 18. The graphical processor 36 typically resides on a video card and is optimized for creating image data that is displayed on an attached display 16.

The main processor 34 performs the signal analysis (steps 120, 125 and 130 in FIG. 5). It is well suited to this task because the audio signal coming from the memory 12 may be in a variety of formats depending on the specific application at hand. This variety in format may also include cached analysis of audio files that may be stored as meta-data in an audio file, as mentioned above.

Once the main processor 34 has performed the correct analysis of the audio signal, a summary of this information is sent to the graphical processor 36.

Typically this summary will be considerably smaller than the audio signal being displayed and also considerably smaller than the resulting image that is displayed on the attached display 16. Therefore the transferring of the summary of analysis from the main processor 34 to the graphical processor 36 is a very efficient task.

The graphical processor 36 receives a summary of the analysis of the audio signal in memory 12 from main processor 34. The Graphical Processor then constructs a waveform image that is shown on the display 16.

This combination of main processor 34 and graphical processor 36 yields a number of performance enhancements. The workload is distributed across two processors where each processor performs a part of the overall processing in a manner that can be optimized for that processor. The communication between the two processors is also very efficient because the amount of information leaving the main processor 34 is smaller in size and can be transmitted in less time. This allows the main processor 34 to return to other tasks, which is of great value to most Digital Audio Workstations. It also allows the specialized graphical processor 36 to be put to better use because it can communicate directly with the attached display 16 faster than the main processor 34.

Hence, the method and apparatus of the present invention thus provides a solution to the aforementioned prior art problem by virtue of representing a signal as an improved waveform in which frequency components of the signal that cannot be displayed at the current time scale of the waveform are represented by various shading of the improved waveform in a single colour. The particular level of shading depends on the frequency components at each time interval of the signal represented by the improved waveform. Therefore, a user of the improved waveform can easily see the locations of the frequency components within the waveform without having to zoom in on the waveform to determine whether further frequency components of the signal represented by the improved waveform are present. Nonetheless, zooming in and out on the improved waveform, i.e. changing the magnification and therefore the time scale, is, of course, possible in the present invention. Another advantage of the present invention is that the same method can be employed to generate the improved waveform irrespective of the time scale being processed.

In addition to the improved waveform displaying the minimum and maximum amplitudes of the signal at each time interval along the improved waveform and the aforementioned frequency component detail, in one embodiment, the present invention can also simultaneously display the RMS amplitude of the signal within each time interval displayed in the improved waveform. This is achieved because the shading varies along the amplitude axis as well as along the time axis.

A further advantage is that the present invention is easier to use by users with imperfect colour vision because different shades of a single colour are employed in the improved waveform. The prior art uses a range of colours to represent the waveform, which can often be problematic for users with imperfect colour vision. This is avoided in the present invention and the user can select the colour to be used in the improved waveform that is most agreeable to the user's colour vision.

The method of the present invention can form part of the suite of functions of a conventional Digital Audio Workstation (DAW) and is implemented in software. The present invention builds on the simplicity and intuitive nature of existing waveform display methods so that greater detail can be displayed and improved workflow can be achieved whilst maintaining a smooth and intuitive progression from microscopic to macroscopic time scales.

Throughout the specification the aim has been to describe the invention without limiting the invention to any one embodiment or specific collection of features. Persons skilled in the relevant art may realize variations from the specific embodiments that will nonetheless fall within the scope of the invention.

1. A method of displaying an audio signal as an improved waveform including:
a) determining samples of the audio signal which represent a waveform based on positions of pixels in the waveform and a time scale of the waveform;
b) calculating minimum and maximum amplitudes of the samples for each pixel on a time axis of the waveform;
c) calculating intensities of frequency components of the samples which cannot be represented at the time scale of the waveform for each pixel on the time axis; and
d) displaying the samples as an improved waveform of amplitude versus time wherein the intensities of the frequency components are represented in the improved waveform by shades of a single colour.

2. The method as claimed in claim 1, wherein the shades of a single colour that are darker represent a higher intensity of high frequency components that cannot be displayed at the time scale of the waveform.

3. The method as claimed in claim 2, wherein the shades of a single colour that are lighter represent a lower intensity of high frequency components that cannot be displayed at the time scale of the waveform.

4. The method as claimed in claim 1, wherein the shades of a single colour that are lighter represent a higher intensity of high frequency components that cannot be displayed at the time scale of the waveform.

5. The method as claimed in claim 4, wherein the shades of a single colour that are darker represent a lower intensity of high frequency components that cannot be displayed at the time scale of the waveform.

6. The method as claimed in claim 1, wherein a gradient between a darkest shade and a lightest shade of the single colour used in the improved waveform is linear.

7. The method as claimed in claim 1, wherein a gradient between a darkest shade and a lightest shade of the single colour used in the improved waveform is curved

8. The method as claimed in claim 1, including:
e) calculating root-mean-square amplitudes of the samples for each pixel on the time axis.

9. The method as claimed in claim 8, including representing the root-mean-square amplitudes of the samples in a profile of amplitude versus colour shade.

10. The method as claimed in claim 1, wherein the shade of a pixel comprising said improved waveform is also indicative of the root-mean-square amplitude of the signal in the time interval represented by said pixel.

11. The method as claimed in claim 1, including representing the root-mean-square amplitude of the signal in the improved waveform as a region of pixels of a darker shade within pixels of a lighter shade, said lighter shade pixels representing maximum and minimum amplitudes of the signal.

12. The method as claimed in claim 1, including repeating steps a)-d) when the time scale of the improved waveform is changed.

13. The method as claimed in claim 1, wherein steps b) and c) are performed in a single step.

14. The method as claimed in claim 8, wherein steps b), c) and e) are performed in a single step.

15. The method as claimed in claim 1, including creating a plurality of overview packets as a summary of a recording of the audio signal enabling some or all of steps a) to d) to be performed without directly accessing the recording.

16. The method as claimed in claim 15, wherein the summary of the audio recording comprises approximations of one or more of the following: minimum amplitudes, maximum amplitudes, a root-mean-square amplitude, high frequency component energies.

17. The method as claimed in claim 1, including transmitting a summary of processing conducted in a main processor to a graphical processor to enable the graphical processor to construct an image of the improved waveform.

18. An apparatus for displaying an audio signal as an improved waveform, said apparatus comprising:
a processor for:
determining samples of the audio signal which represent a waveform based on positions of pixels in the waveform and a time scale of the waveform;
calculating maximum and minimum amplitudes of the samples for each pixel on a time axis; and
calculating intensities of frequency components of the samples which cannot be represented at the time scale of the waveform for each pixel on the time axis; and
a display coupled to be in communication with the processor for displaying the samples as an improved waveform of amplitude versus time wherein the intensities of the frequency components are represented in the waveform by shades of a single colour.

19. The apparatus of claim 18, wherein the processor comprises a main processor coupled to be in communication with a graphical processor, said graphical processor coupled to be in communication with the display.

20. The apparatus of claim 19, wherein the main processor creates a plurality of overview packets as a summary of a recording of the audio signal enabling some or all of the steps performed in the main processor to be performed without directly accessing the recording.

21. The apparatus of claim 20, wherein the main processor transmits the summary to the graphical processor to enable the graphical processor to construct an image of the improved waveform.
